(19) United States
(12) Patent Application Publication
(10) Pub. No.: US 2011/0180127 A1
(43) Pub. Date: Jul. 28, 2011

(54) SOLAR CELL FABRICATION BY NANOIMPRINT LITHOGRAPHY

(75) Inventors: Fen Wan, Austin, TX (US); Shuqiang Yang, Austin, TX (US); Frank Y. Xu, Round Rock, TX (US); Weijun Liu, Cedar Park, TX (US); Edward Brian Fletcher, Austin, TX (US); Sidlgata V. Sreenivasan, Austin, TX (US); Michael N. Miller, Austin, TX (US); Darren D. Donaldson, Austin, TX (US)

(73) Assignee: MOLECULAR IMPRINTS, INC., Austin, TX (US)

(21) Appl. No.: 13/016,006

(22) Filed: Jan. 28, 2011

Related U.S. Application Data
(60) Provisional application No. 61/299,001, filed on Jan. 28, 2010.
(60) Provisional application No. 61/299,484, filed on Jan. 29, 2010.
(60) Provisional application No. 61/299,451, filed on Jan. 29, 2010.

(51) Int. Cl. H01L 31/02; H01L 31/0232

(52) U.S. Cl. 136/252; 438/72; 257/E31.127

(57) ABSTRACT

Fabricating a solar cell stack includes forming a nanopatterned polymeric layer on a first surface of a silicon wafer and etching the first surface of the silicon wafer to transfer a pattern of the nanopatterned polymeric layer to the first surface of the silicon wafer. A layer of reflective electrode material is formed on a second surface of the silicon wafer. The nanopatterned first surface of the silicon wafer undergoes a buffered oxide etching. After the buffered oxide etching, the nanopatterned first surface of the silicon wafer is treated to decrease a contact angle of water on the nanopatterned first surface. Electron donor material is deposited on the nanopatterned first surface of the silicon wafer to form an electron donor layer, and a transparent electrode material is deposited on the electron donor layer to form a transparent electrode layer on the electron donor layer.

### CROSS-REFERENCE TO RELATED APPLICATIONS

This application claims priority to U.S. Application Ser. No. 61/299,001 filed Jan. 28, 2010, U.S. Application Ser. No. 61/299,451 filed Jan. 29, 2010, and U.S. Application Ser. No. 61/299,484 filed Jan. 29, 2010, each of which is incorporated by reference herein in its entirety.

### TECHNICAL FIELD

The present invention relates to solar cell fabrication by methods including nanoimprint lithography.

### BACKGROUND

Nano-fabrication includes the fabrication of very small structures that have features on the order of 100 nanometers or smaller. One application in which nano-fabrication has had a sizeable impact is in the processing of integrated circuits. The semiconductor processing industry continues to strive for larger production yields while increasing the circuits per unit area formed on a substrate, therefore nano-fabrication becomes increasingly important. Nano-fabrication provides greater process control while allowing continued reduction of the minimum feature dimensions of the structures formed. Other areas of development in which nano-fabrication has been employed include biotechnology, optical technology, mechanical systems, and the like.

An exemplary nano-fabrication technique in use today is commonly referred to as imprint lithography. Exemplary imprint lithography processes are described in detail in numerous publications, such as U.S. Patent Publication No. 2004/0065976, U.S. Patent Publication No. 2004/0065252, and U.S. Pat. No. 6,936,194, all of which are hereby incorporated by reference herein.

An imprint lithography technique disclosed in each of the aforementioned U.S. patent publications and patent includes formation of a relief pattern in a formable (polymerizable) layer and transferring a pattern corresponding to the relief pattern into an underlying substrate. The substrate may be coupled to a motion stage to obtain a desired positioning to facilitate the patterning process. The patterning process uses a template spaced apart from the substrate and a formable liquid applied between the template and the substrate. The formable liquid is solidified to form a layer that has a pattern conforming to a shape of the surface of the template that contacts the formable liquid. After solidification, the template is separated from the layer such that the template and the substrate are spaced apart. The substrate and the solidified layer are then subjected to additional processes to transfer a relief image into the substrate that corresponds to the pattern in the solidified layer.

### SUMMARY

In one aspect, fabricating a solar cell stack includes forming a nanopatterned polymeric layer on a first surface of a silicon wafer. The first surface of the silicon wafer is etched to transfer a pattern of the nanopatterned polymeric layer to the first surface of the silicon wafer, thereby forming a nanopatterned first surface of the silicon wafer having recessions and protrusions. A layer of a reflective electrode material is formed on a second surface of the silicon wafer, wherein the second surface of the silicon wafer is opposite the nanopatterned first surface of the silicon wafer. The nanopatterned first surface of the silicon wafer undergoes buffered oxide etching after the layer of reflective electrode material is formed on the second surface of the silicon wafer. The nanopatterned first surface of the silicon wafer is treated after buffered oxide etching to decrease a contact angle of water on the nanopatterned first surface of the silicon wafer. An electron donor material is deposited on the nanopatterned first surface of the silicon wafer to form an electron donor layer on the nanopatterned first surface of the silicon wafer, and a transparent electrode material is deposited on the electron donor layer to form a transparent electrode layer on the electron donor layer.

In some implementations, etching the first surface of the silicon wafer includes a dry etching process. In other implementations, etching the second surface of the silicon wafer includes a wet etching process, such as wet etching with potassium hydroxide. In some cases, the reflective electrode material includes aluminum. A contact angle of water on the nanopatterned first surface of the silicon wafer after buffered oxide etching can be between about 40° and about 50°. Treating the nanopatterned first surface of the silicon wafer after buffered oxide etching can include UV ozone treatment of the silicon wafer. A resistivity of the silicon wafer following the UV ozone treatment can be about 120% or less, 110% or less, or 105% or less of the resistivity of the silicon wafer before the UV ozone treatment. In some cases, the nanopatterned first surface of the silicon wafer can be cleaned (e.g., with other etching processes or with Piranha solution) before forming the layer of the reflective electrode material on the second surface of the silicon wafer.

In some implementations, the electron donor material and/or the transparent electrode material includes poly(3,4-ethylenedioxythiophene) poly(styrene-sulfonate) (PEDOT:PSS). In some cases, depositing the electron donor material on the nanopatterned first surface of the silicon wafer includes electrodepositing the electron donor material in recessions of the nanopatterned first surface of the silicon wafer.

In another aspect, fabricating a solar cell stack includes patterning a surface of a substrate to form a nanopatterned surface and depositing a conformal layer of a reflective electrode material on the nanopatterned surface of the substrate. A conformal layer of a first electrically conductive organic material is deposited on the reflective electrode material, and a layer of a second electrically conductive organic material is deposited on the first electrically conductive organic material. A buffer material is then deposited on the second electrically conductive organic material, and a transparent electrode material is deposited on the buffer material.

In some implementations, depositing the layer of the second electrically conductive organic material on the first electrically conductive organic material includes filling recesses and covering protrusions in the conformal layer of the first electrically conductive organic material with the second electrically conductive organic material. The transparent electrode material, the electrode donor material, or the buffer material can include poly(3,4-ethylenedioxythiophene) poly(styrenesulfonate) (PEDOT:PSS). A second buffer material can be deposited between the reflective electrode material and the first electrically conductive organic material.

Certain implementations include a solar cell stack formed by any combination of features described herein. Other implementations include a solar cell including a solar cell stack formed by any combination of features described herein.

Although methods and materials similar or equivalent to those described herein can be used in the practice or testing of the present embodiments, suitable methods and materials are described below. All publications, patent applications, patents, and other references mentioned are incorporated by reference herein. In case of conflict, the present specification, including definitions, will control. The materials, methods, and examples are illustrative only and not intended to be limiting. It should be appreciated by those skilled in the art that the conception and the specific embodiments disclosed may be readily utilized as a basis for modifying or designing other structures for carrying out the same purposes as described herein. It should also be realized by those skilled in the art that such equivalent constructions do not depart from the spirit and scope as set forth in the appended claims.

### BRIEF DESCRIPTION OF DRAWINGS

FIG. 1 illustrates a side view of a lithographic system.

FIG. 2 illustrates a side view of the substrate illustrated in FIG. 1, having a patterned layer thereon.

FIG. 3 illustrates a side view of a planar design for a hybrid solar cell.

FIGS. 4A-4C depict the formation of a nanopatterned active layer for a device such as a photovoltaic cell.

FIG. 5 illustrates a side view of a solar cell with a patterned active layer.

FIG. 6 illustrates a side view of a solar cell in with a patterned active layer.

FIGS. 7A-7E illustrate steps in a process for forming a solar cell.

FIGS. 8A-8H illustrate steps in a process for forming a solar cell.

FIGS. 9A-9B illustrate cross-sectional views of a solar cell with an active layer formed by nanoimprint lithography.

FIG. 10 is a flow chart showing steps in a nanoimprint lithography hybrid solar cell fabrication process with dry etching of a substrate.

FIGS. 11A and 11B are scanning electron micrograph images of a cross section of an etched n-type silicon wafer filled with poly(3,4-ethylenedioxythiophene) poly(styrenesulfonate) (PEDOT:PSS).

FIG. 12 is a flow chart showing steps in a nanoimprint lithography hybrid solar cell fabrication process with wet etching of a substrate.

FIG. 13 is a flow chart showing steps in an organic solar cell fabrication process using nanoimprint lithography.

FIG. 14 illustrates a cross section of an organic solar cell formed by the process in FIG. 13.

FIG. 15A shows a scanning electron micrograph of a patterned substrate formed by nanoimprint lithography for use in an organic solar cell.

FIG. 15B shows a scanning electron micrograph of a patterned organic solar cell stack formed on a patterned substrate.

### DETAILED DESCRIPTION

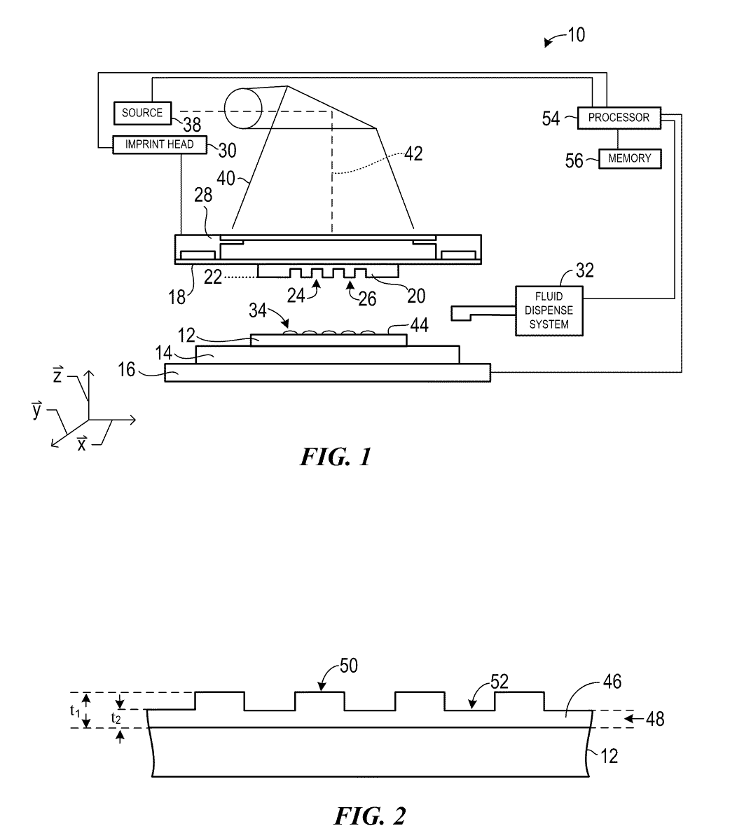

Referring to the figures, and particularly to FIG. 1, illustrated therein is a lithographic system 10 used to form a relief pattern on substrate 12. Substrate 12 may be coupled to substrate chuck 14. As illustrated, substrate chuck 14 is a vacuum chuck. Substrate chuck 14, however, may be any chuck including, but not limited to, vacuum, pin-type, groove-type, electrostatic, electromagnetic, and/or the like. Exemplary chucks are described in U.S. Pat. No. 6,873,087, which is incorporated by reference herein.

Substrate 12 and substrate chuck 14 may be further supported by stage 16. Stage 16 may provide translational and/or rotational motion along the x, y, and z-axes. Stage 16, substrate 12, and substrate chuck 14 may also be positioned on a base (not shown).

Spaced-apart from substrate 12 is template 18. Template 18 may include a body having a first side and a second side with one side having a mesa 20 extending therefrom towards substrate 12. Mesa 20 has a patterning surface 22 thereon. Further, mesa 20 may be referred to as mold 20. Alternatively, template 18 may be formed without mesa 20.

Template 18 and/or mold 20 may be formed from such materials including, but not limited to, fused-silica, quartz, silicon, organic polymers, siloxane polymers, borosilicate glass, fluorocarbon polymers, metal, hardened sapphire, and/or the like. As illustrated, patterning surface 22 includes features defined by a plurality of spaced-apart recesses 24 and/or protrusions 26, though patterning surfaces can also have other configurations (e.g., planar). Patterning surface 22 may define any original pattern that forms the basis of a pattern to be formed on substrate 12.

Template 18 may be coupled to chuck 28. Chuck 28 may be configured as, but not limited to, vacuum, pin-type, groove-type, electrostatic, electromagnetic, and/or other similar chuck types. Exemplary chucks are further described in U.S. Pat. No. 6,873,087, which is incorporated by reference herein. Further, chuck 28 may be coupled to imprint head 30 such that chuck 28 and/or imprint head 30 may be configured to facilitate movement of template 18.

System 10 may further include a fluid dispense system 32. Fluid dispense system 32 may be used to deposit formable material 34 (e.g., polymerizable material) on substrate 12. Formable material 34 may be positioned upon substrate 12 using techniques, such as, drop dispense, spin-coating, dip coating, chemical vapor deposition (CVD), physical vapor deposition (PVD), thin film deposition, thick film deposition, and/or the like. Formable material 34 may be disposed upon substrate 12 before and/or after a desired volume is defined between mold 22 and substrate 12 depending on design considerations. Formable material 34 may be functional nano-particles having use within the bio-domain, solar cell industry, battery industry, and/or other industries requiring a functional nano-particle. For example, formable material 34 may comprise a monomer mixture as described in U.S. Pat. No. 7,157,036 and U.S. Patent Publication No. 2005/0187339, both of which are incorporated by reference herein. Alternatively, formable material 34 may include, but is not limited to, biocompatible materials (e.g., polyethylene glycol (PEG)), solar cell materials (e.g., n-type and p-type materials), and the like.

Referring to FIGS. 1 and 2, system 10 may further include energy source 38 coupled to direct energy 40 along path 42. Imprint head 30 and stage 16 may be configured to position template 18 and substrate 12 in superimposition with path 42. System 10 may be regulated by processor 54 in communication with stage 16, imprint head 30, fluid dispense system 32, and/or source 38, and may operate on a computer readable program stored in memory 56.

Either imprint head 30, stage 16, or both vary a distance between mold 20 and substrate 12 to define a desired volume therebetween that is filled by formable material 34. For example, imprint head 30 may apply a force to template 18 such that mold 20 contacts formable material 34. After the desired volume is filled with formable material 34, source 38 produces energy 40, e.g., ultraviolet radiation, causing formable material 34 to solidify and/or cross-link, conforming to a shape of surface 44 of substrate 12 and patterning surface 22, defining patterned layer 46 on substrate 12. Patterned layer 46 may comprise a residual layer 48 and a plurality of features shown as protrusions 50 and recessions 52, with protrusions 50 having a thickness t₁ and residual layer having a thickness t₂.

The above-mentioned system and process may be further employed in imprint lithography processes and systems referred to in U.S. Pat. No. 6,932,934, U.S. Pat. No. 7,077,992, U.S. Pat. No. 7,179,396, and U.S. Pat. No. 7,396,475, all of which are incorporated by reference herein.

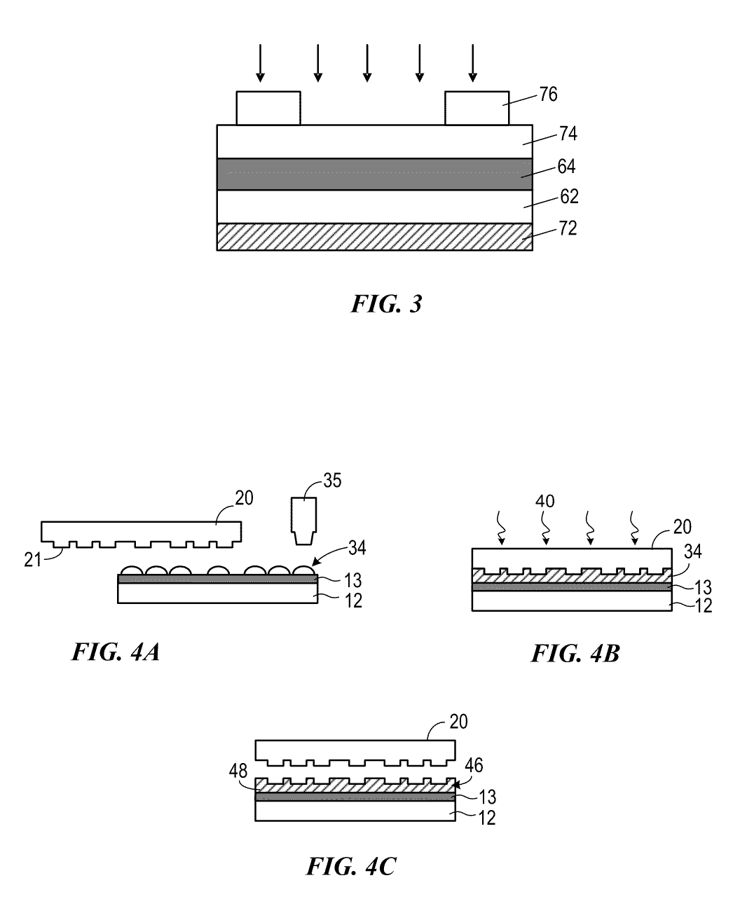

Commercial solar cells are generally built from inorganic materials (e.g., silicon, CuInGaSe, CdTe, and the like). Hybrid solar cells and organic solar cells may offer a low-cost alternative to the conventional solar cells. Hybrid solar cells generally include organic and inorganic materials with a p-n junction formed therebetween. Planar hybrid solar cells have been studied with n-type silicon, TiO₂, ZnO, and the like, as electron acceptors. An example of a planar solar cell is shown in FIG. 3, with cathode 72, electron acceptor layer 62, electron donor layer 64, transparent conductor 74, and anodes (or anode grid) 76. Light impinges on transparent conductor 74 as shown by the arrows. Power conversion efficiency (PCE) of these cells, however, can be relatively low. Described herein are nanoimprint lithography systems and methods for fabricating high efficiency, low cost organic and hybrid nano-structured solar cells. In some cases, these nano-structured organic and hybrid solar cells can provide increased light absorption, output current, and PCE relative to planar solar cells.

FIGS. 4A-4C depict the formation of a nanopatterned conductive polymer for a device such as a photovoltaic cell. The photovoltaic cell may be an organic photovoltaic cell or hybrid photovoltaic cell. As depicted in FIG. 4A, mold 20, which may have release layer 21, is oriented with respect to substrate 12. One or more layers 13 may be present on the substrate. Layer 13 may be, for example, an adhesion layer, a hard mask layer, or the like. A polymerizable composition 34 may be applied to the substrate 12 (or additional layer 13) using, for example, dispenser 35 to form a multiplicity of drops on the substrate. The polymerizable composition 34 may include one or more polymer precursors curable with ultraviolet light.

In FIG. 4B, polymerizable composition 34 is contacted with mold 20. Mold 34 is illuminated with UV radiation 40 to solidify the polymerizable material. Polymerization may occur at room temperature and atmospheric pressure. After polymerizable composition 34 is solidified, mold 20 is separated from substrate 12, as shown in FIG. 4C, leaving a nanopatterned layer 46 (with residual layer 48) adhered to substrate 12 (or to additional layer 13).

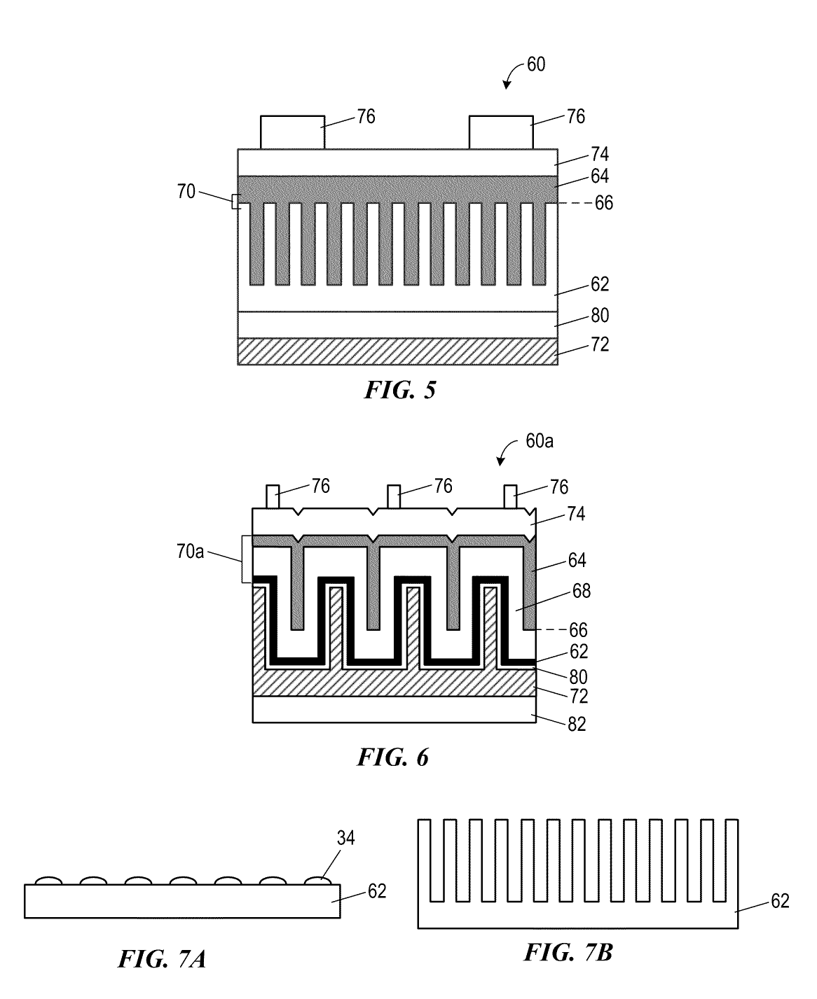

Referring to FIG. 5, solar cell 60 is illustrated having electron acceptor layer 62 (n-type material) and electron donor layer 64 (p-type material). When solar cell 60 is a hybrid solar cell, electron acceptor layer 62 may be an inorganic layer formed of materials including, but not limited to, mono-crystalline silicon, polycrystalline silicon, or hydrogenated amorphous silicon, and electron donor layer 64 may be an organic layer formed of materials including, but not limited to, poly(3,4-ethylenedioxythiophene) poly(styrenesulfonate) (PEDOT:PSS), poly(3-hexylthiophene) (P3HT), copper phthalocyanine (CuPc), and the like. When solar cell 60 is an organic solar cell, electron acceptor layer 62 may include C60, C70, or a derivative thereof, and electron donor layer 64 can include a p-type organic conductor such as PEDOT:PSS, P3HT, or the like.

A patterned interface 66 may be formed between electron acceptor layer 62 and electron donor layer 64 at p-n junction 70. In some cases, an intrinsic layer may be positioned between electron acceptor layer 62 and electron donor layer 64. For example, as illustrated in FIG. 6, solar cell 60a may be formed with electron acceptor layer 62, and intrinsic layer 68 may be positioned at interface 66 such that a p-i-n junction 70a is formed with electron donor layer 64.

Solar cells 60 and 60a may further include a cathode 72 positioned adjacent to electron acceptor layer 62. Cathode 72 may be formed of materials including, but not limited to, metals, polymers, carbon, carbon-metal alloys, and the like. Additionally, solar cells 60 and 60a may include a transparent conductor 74 positioned adjacent to electron donor layer 64. Transparent conductor 74 may include materials such as ITO, SnO₂, ZnO, and the like. In some cases, an organic material, such as PEDOT:PSS may function as a transparent conductor. As such, if electron donor layer 64 is a transparent conductor, transparent conductor 74 can be optional. Additionally, an anode grid 76 may be formed on solar cell 60 or 60a adjacent transparent conductor 74 or electron donor layer 64.

An optional buffer layer 80 may be positioned between cathode 72 and electron acceptor layer 62. Buffer layer 80 may allow better contact between electron acceptor layer 62 and cathode 72. Buffer layer 80 may be formed of materials including, but not limited to, ZnO, SnO2, and the like.

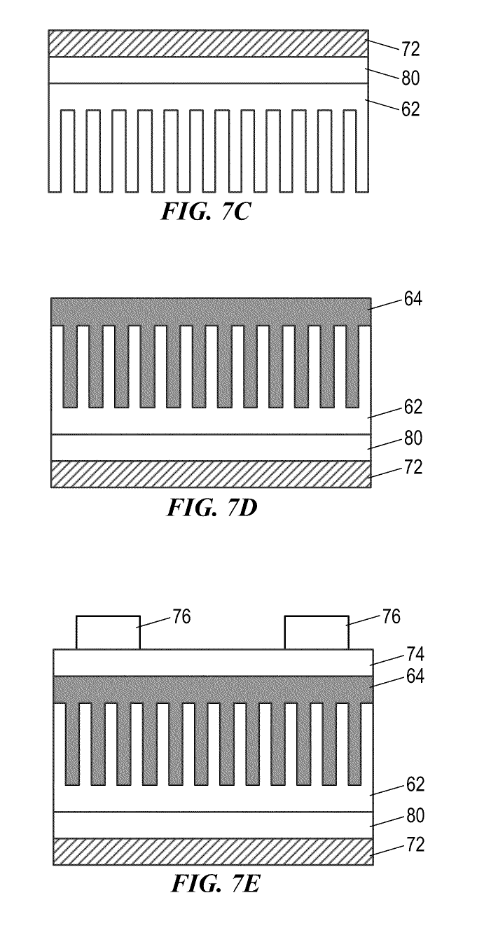

FIGS. 7A-7E illustrate a method for forming solar cell 60 having electron donor layer 64 and electron acceptor layer 62. Referring to FIGS. 7A and 7B, polymerizable material 34 may be deposited on electron acceptor layer 62 and patterned using the systems and processes described in relation to FIGS. 1 and 2. Features may be transferred into electron acceptor layer 62. The features in electron acceptor layer 62 may include pillars having a diameter between approximately 10 nm and 1 μm and a height of greater than approximately 50 nm.

Referring to FIG. 7C, optional buffer layer 80 may be positioned on electron acceptor layer 62. Additionally, cathode 72 may be deposited on buffer layer 80 and/or electron acceptor layer 62, depending on design considerations (e.g., whether buffer layer 80 is present). Referring to FIG. 7D, electron donor layer 64 may be positioned on electron acceptor layer 62. Electron donor layer 64 may be positioned using techniques including, but not limited to, spin-coating, ink-jetting material deposition, doctor blading, and the like. Referring to FIG. 7E, conductor 74 may be positioned on electron donor layer 64. Conductor 74 may be transparent. If electron donor layer 64 is a transparent conductor (e.g., PEDOT:PSS), conductor 74 may be optional. Additionally, anode grid 76 may be positioned on conductor 74 or electron donor layer 64 depending on design considerations (e.g., whether conductor 74 is present).

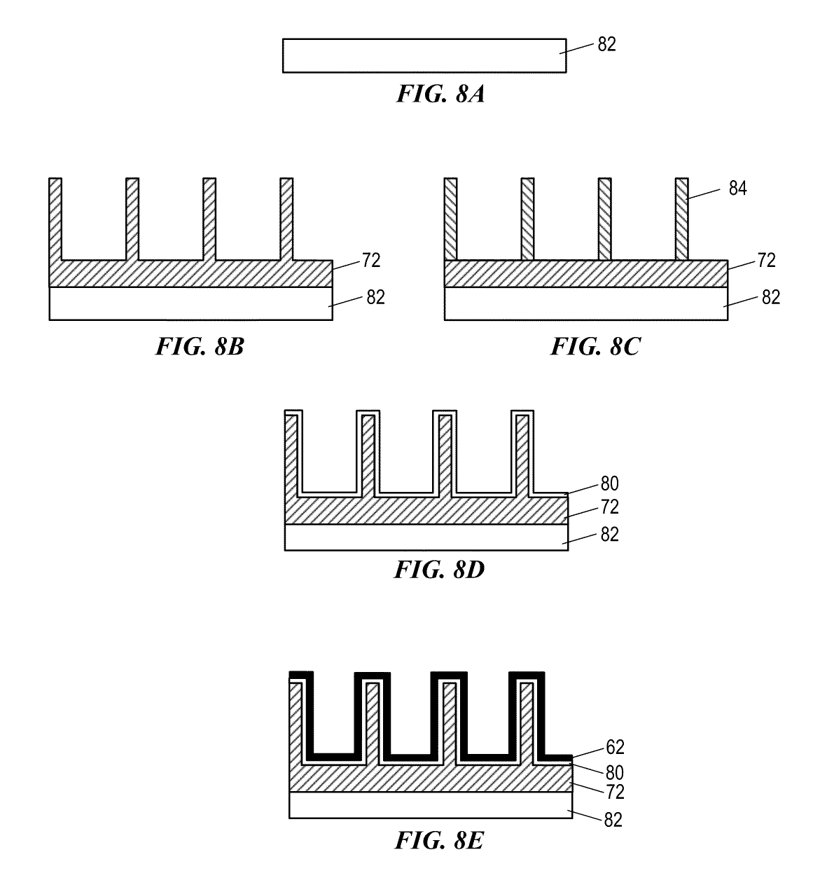

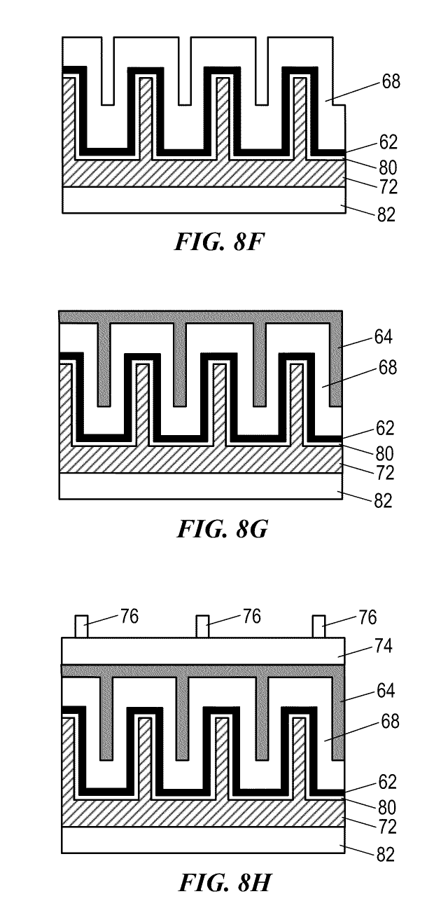

FIGS. 8A-8H illustrate an exemplary method for forming solar cell 60a having electron donor layer 64, electron acceptor layer 62, and intrinsic layer 68. Referring to FIGS. 8A and 8B, cathode 72 may be deposited on a substrate layer 82 and patterned. Cathode 72 may be patterned using systems and techniques described in relation to FIGS. 1, 2, 7A, and 7B. Alternatively, a separate patterned layer 84 may be positioned on cathode 72, as illustrated in FIG. 8C. Patterned layer 84 may be formed of materials including, but not limited to, polymers, transparent dielectrics, metals, and the like. Separate patterned layer 84 may be used to allow an alternative patterning process, enhanced absorption, and the like, depending on material selection and design considerations.

Referring to FIG. 8D, a conformal buffer layer 80 may be deposited on cathode 72. Buffer layer 80 may be formed of materials including, but not limited to, ZnO, SnO2, and the like. A conformal electron acceptor layer 62 may be deposited on buffer layer 80 as shown in FIG. 8E. Electron acceptor layer 62 may be deposited using techniques including, but not limited to, CVD, PVD, PECVD, hot-wire-CVD, and the like. Additionally, as shown in FIG. 8F, a conformal intrinsic layer 68 may be deposited on electron acceptor layer 62 using, for example, one of these techniques.

Referring to FIG. 8G, electron donor layer 64 may be deposited on intrinsic layer 68. electron donor layer 64 may be deposited using techniques including, but not limited to, spin-coating, ink-jet material deposition, doctor blading, and the like.

Referring to FIG. 8H, conductor 74 may be positioned on electron donor layer 64. Conductor 74 may be transparent. If electron donor layer 64 is a transparent conductor (e.g., PEDOT:PSS), the additional conductor 74 may be optional. Additionally, anode grid 76 may be positioned on conductor 74 or electron donor layer 64 depending on design considerations.

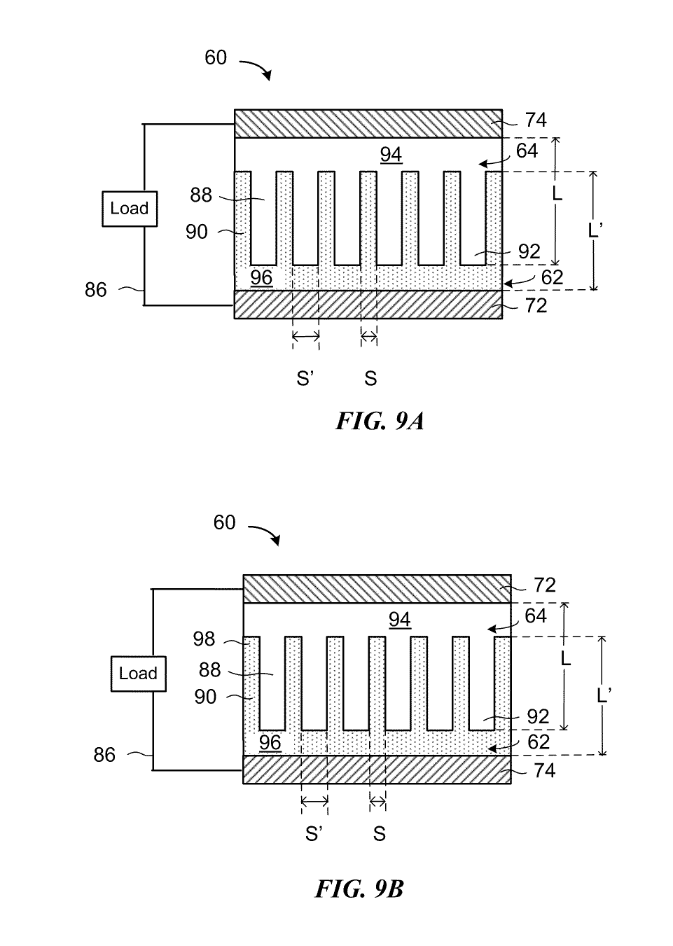

FIG. 9A illustrates a cross-sectional view of a portion of another embodiment of solar cell 60 formed at least in part by a nanoimprint lithography process. Solar cell 60 can be an organic solar cell or a hybrid solar cell. Solar cell 60 includes electron donor layer 64 and electron acceptor layer 62 sandwiched between transparent electrode 74 and reflective electrode 72. Electron donor layer 64 and/or electron acceptor layer 62 may include an electrically conductive polymer or inorganic semiconductor. The conductive polymer may be organic (e.g., carbon-containing and substantially non-metal-containing) or an organic-inorganic hybrid (e.g., carbon-containing and metal-containing). The conductive polymer may be conjugated. The inorganic semiconductors may be TiO₂, ZnO, GeTe, etc. The electron donor layer 64 layer may include small inorganic molecules including CuPc, ZnPc, etc.

Electrical circuit 86 is formed between transparent electrode 74 and reflective electrode 72. Reflective electrode 72 is able to reflect electromagnetic radiation present in solar energy and may include, for example, aluminum, zinc, cadmium, and other low work function metals. Transparent electrode 74 is substantially transparent to electromagnetic radiation present in solar energy. Transparent electrode 74 may function as an electron collection electrode. In an example, transparent electrode 74 is formed of glass coated with indium tin oxide. In another example, transparent electrode 74 may include a conductive polymer such as PEDOT:PSS.

An electrode made of doped conductive polymer with high conductivity, high transparency to electromagnetic radiation, and a high work function may be used as an anode in organic and organic-inorganic hybrid cells. The conductive polymer electrode can be non-rigid, and can be used in place of a more rigid electrode with a lower work function, such as glass coated with indium tin oxide. Conductive polymers that may be used as electrodes in solar cells described herein include, for example, PEDOT:PSS and other doped conjugated polymers. In an example, CLEVIOS PH500 (available from H.C. Starck, Germany), is a PEDOT:PSS that can achieve a sheet resistance of less than 500 ohm/square and a transmission of 75% at a thickness of 200 nm with one or more selected polar solvents with a high boiling point (e.g., ethylene glycol).

Advantages of using conductive (e.g., conjugated) polymers as electrodes for solar cells may include a high work function, which allows efficient hole extraction. Other advantages include processibility, which allows better control of surface planarity, and increased adhesion between layers (e.g., between polymer layers with similar chemical properties). Electrodes formed from conductive polymers are advantageously flexible (i.e., not rigid), allowing implementation in a variety of configurations, including tandem cell arrays, V-shaped cells, and the like, which may be used to enhance power conversion efficiency. Additionally, fabrication costs for electrodes formed from conductive polymers may be less than for electrodes formed from more rigid materials.

Use of a conductive polymer as the anode in solar cells with a nanopatterned active layer (e.g., a nanopatterned electron donor layer or electron acceptor layer) allows fabrication of solar cells from the anode or from the cathode. That is, the active layer may be formed on the cathode (the reflective electrode) and the anode formed on the active layer, or the active layer may be formed on the anode (the transparent electrode), and the cathode formed on the active layer. One or more conductive polymers or a mixture thereof can be deposited on the first active layer by spin coating, inkjet printing, and the like, to form a conductive, transparent electrode.

Referring again to FIG. 9A, protrusions 88 of electron donor layer 64 are interleaved with protrusions 90 of electron acceptor layer 62, with a width of protrusions 90 defining a spacing S between protrusions 88, and a width of protrusions 88 defining a spacing S′ between protrusions 90. In some embodiments, the protrusions 88 and 90 are substantially equal in width, and spacings S and S′ are substantially the same.

Spacings S and S′ may be selected to be on the order of the distance electrons and holes are able to diffuse through either the electron donor material or the electron acceptor material, such that electrons are transferred efficiently from the electron donor to the electron acceptor and the holes in the solar cell are able to diffuse from an acceptor layer to a donor layer. For some electron donor and electron acceptor materials, the distance electrons are able to diffuse through the material is less than about 20 nm (e.g., between about 5 nm and about 20 nm, or between about 10 nm and about 20 nm).

A depth of the recesses between protrusions 88 and 90, or a length L of protrusions 88 and a length L′ of protrusions 90, can be selected such that solar energy is relatively efficiently captured. L and L′ may be, for example, at least about 50 nm, at least about 100 nm, at least about 200 nm, at least about 300 nm, or at least about 400 nm. In some cases, L and L′ are substantially the same. In solar cell 60, with S substantially equal to S′ and L substantially equal to L′, a ratio of L/S may be at least about 5, at least about 10, at least about 20, or greater.

As shown in FIG. 9A, residual layer 96 of electron acceptor layer 62 is in contact with reflective electrode 72 and residual layer 94 of electron donor layer 64 is in contact with transparent electrode 74. This may be achieved by forming a patterned electron acceptor layer 62 on a reflective electrode 72 or by forming a patterned electron donor layer 64 on transparent electrode 74. In some cases, however, as shown in FIG. 9B, electron donor layer 64 is in contact with reflective electrode 72, and electron acceptor layer 62 is in contact with transparent electrode 74. This may be achieved by forming a patterned electron donor layer 64 on a reflective electrode 72 or by forming a patterned electron acceptor layer 62 on transparent electrode 74. In some cases, rather than forming a pattern including protrusions and recesses in, for example, an electron acceptor layer or an electron donor layer, a multiplicity of recesses may be formed (e.g., etched) in the electron acceptor layer or the electron donor layer.

In an example, patterned electron acceptor layer 62 is formed by a nano-imprint lithography process on reflective electrode 72. Electron acceptor layer 62 may be formed by depositing polymerizable electron acceptor material on reflective electrode 72 and forming protrusions and recesses as described with respect to FIGS. 3A-3C. In some cases, electron acceptor layer 62 is formed by using a nano-imprint lithography process to etch a desired pattern in an electron acceptor material, such as n-type silicon. A reflective electrode may be coupled to the electron acceptor material before or after etching. Electron donor material may be deposited in recesses 92 of electron acceptor layer 62 (e.g., between or around protrusions 90 of the electron acceptor layer) to form “protrusions” 88. Electron donor material may also be deposited on top of the protrusions 90 of the electron acceptor layer to form “residual layer” 94. Transparent electrode 74 may be formed on top of layer 94.

Electrochemical polymerization (or electropolymerization) may be used to deposit one or more donor materials in recesses 92 in electron acceptor layer 62 (e.g., between protrusions 90 in the electron acceptor layer) to form “protrusions” 88. The donor material may include a conductive polymer. In this process, a polymerizable liquid may be placed in the recesses in the electron acceptor layer 62. In some cases, the recesses are substantially filled with the polymerizable liquid. The polymerizable liquid may include monomers capable of forming conductive polymers with a low bandgap, such as polyacetylene, polypyrrole, polythiophene, polyaniline, polyfluorene, and any combination or derivative thereof. In an example, the polymerizable liquid includes 3-hexylthiophene, and the conductive polymer includes poly-3-hexylthiophene.

The polymerizable liquid used to form the electron donor layer may include a solvent, an electrolyte, one or more additional additives, or a combination thereof. Examples of solvents include chlorobenzene, acetonitrile, dichlorobenzene, water, and the like. Examples of electrolytes include sulfuric acid, hypochlorite salts, and the like. If a solvent is used, it may be selected to be compatible (e.g., miscible) with the chosen monomers. Some monomers, for example, thiophene, may be combined with a small amount of solvent or with no solvent.

Deposition of the donor material from the bottom of the well up allows the recesses in the acceptor layer to be filled with donor material at an L/S ratio of up to about 400 substantially without the formation of voids in the donor material. With the small spacing S between acceptor and donor (e.g., about 5-20 nm), and the substantial absence of voids in the acceptor material and the donor material, the resulting solar cell can demonstrate high conversion efficiency.

In some cases, S and S′ may be in a range between about 100 nm and about 300 nm, or other size. Thus, the PCE of a nanopatterned solar cell can exceed the PCE of a planar solar cell of the same material, based at least in part on the increased surface area and light trapping of the nanopatterned electron donor and acceptor layers.

Referring again to FIGS. 3A-C, forming a patterned active layer by imprint lithography may include photopolymerizing a polymerizable composition including conductive polymer precursors and a cationic photoinitiator to form an electron donor layer. The cationic photoinitiators may be soluble in the polymer precursors (e.g., monomers). Thus, photopolymerization may be performed in the absence of a solvent. In some cases, photopolymerization may occur in the presence of a solvent such as, for example, tetrahydrofuran. Examples of conductive polymer precursor/cationic photoinitiator combinations include pyrrole and iron-arene salts, thiophene and iodonium salts, and the like.

Nano-imprinting of conductive polymer (e.g., electron donor or p-type) materials with cationic photoinitiators may be achieved by UV curing at room temperature. For example, p-type materials for organic light emitting devices (OLEDs) and organic photovoltaic (OPV) cells can be fabricated by UV curing of polymerizable compositions including conducting (e.g., conjugated) polymer precursors and a cationic photoinitiator. This process allows the formation, through nano-imprint lithography, of a nanopatterned layer including features (e.g., nano-pillars, recesses, and the like) with a spacing of about 5-20 nm, or on the order of the diffusing distance of charge carriers or excitons in the conductive polymer.

FIG. 9B depicts an active layer formed by nano-imprint lithography, sandwiched between reflective electrode 72 and transparent electrode 74. The p-type material of the electron donor layer 64 may include polythiophene or other conductive polymers with a low bandgap. The electron acceptor layer of the electron acceptor layer 62 may include [6,6]-phenyl C₆₁-butyric acid methyl ester (PCBM) or other n-type material. The reflective electrode 72 may include, for example, aluminum. The transparent electrode 74 may include a conductive polymer such as, for example, poly(3,4-ethylenedioxythiophene) poly(styrenesulfonate) (PEDOT:PSS).

Recesses 98 in the electron donor (p-type) layer 64 may be spaced about 20 nm apart or less (e.g., about 5-20 nm apart, or about 10-20 nm apart). The recesses in the electron donor layer 64 may be substantially filled with electron acceptor (n-type) material that has been, for example, spin coated, electrochemically deposited, or vapor deposited on the electron donor material. The n-type material may substantially fill the recesses in the electron donor layer and form a layer over the electron donor layer. A reflective electrode 72 may be formed to substantially cover the electron acceptor layer 62. A transparent electrode 74 may be formed on the electron donor layer 64. An electrical circuit 86 may be formed between reflective electrode 72 and transparent electrode 74. A depth of the n-type material may be, for example, less than about 1 μm, but at least about 50 nm. A ratio of the depth of the n-type material to the spacing between the p-type recesses may be at least about 2.

The power conversion efficiency of a hybrid solar cell including an etched silicon wafer (e.g., as illustrated in FIG. 9A, in which the electron acceptor or electron donor is a silicon wafer, and recesses and protrusions are formed by etching the silicon wafer) may be improved by processes including cleaning of the silicon wafer after etching to remove contaminants left on the wafer by the hard mask and/or the etchant, treating the surface of the silicon wafer to alter the surface properties (e.g., hydrophilic/hydrophobic nature) of the etched silicon surface. Such processes may reduce interface resistance and allow wetting of the etched surface with an electron donor or acceptor material selected to fill the recesses between the protrusions, such that the electron donor or acceptor material substantially fills the recesses, achieving good contact between the electron donor or acceptor material and the silicon wafer.

When a hybrid solar cell includes a patterned electron donor or acceptor layer formed by etching a silicon wafer, processing steps may be selected to increase the PCE of the resulting hybrid solar cell. These processing steps include, for example, removal of traces or by-products of etchants, hard mask materials, or both, followed by treatment of the surface of the patterned silicon layer to remove silicon dioxide on the surface and/or to allow controlled growth of silicon dioxide on the surface to enhance wetting of the silicon surface by the organic electron donor or acceptor material (e.g., in a spin-coating process). Removal of some or all of a silicon dioxide layer from the surface of a silicon wafer can reduce interface resistance and contribute to an increase in the PCE of the resulting hybrid solar cell.

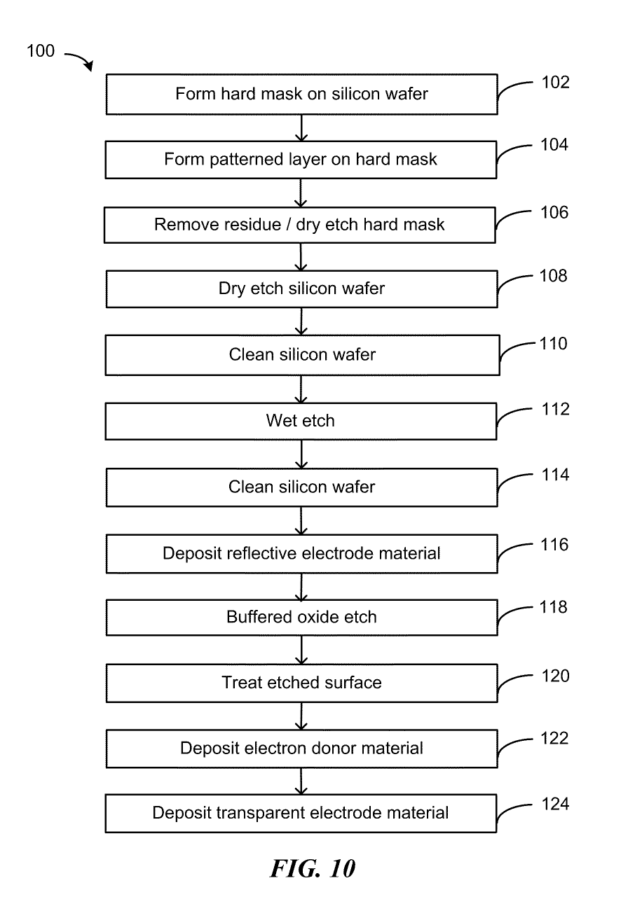

A hybrid solar cell can be fabricated by a process including patterning a silicon wafer, cleaning the etched wafer to remove contaminants and by-products of the etching process, treating the etched surface to remove and/or grow silicon dioxide on the surface to achieve a suitable combination of interface resistance and wetting properties, and filling recesses in the etched silicon surface with an electron donor or acceptor material, as needed. Referring to the flowchart in FIG. 10, a process 100 for fabricating a hybrid solar cell with a patterned electron acceptor is described. As an example, the process is described with a silicon wafer as the electron acceptor. In some cases, one or more steps in process 100 may be performed in an order other than that shown in FIG. 10. In certain cases, one or more steps in process 100 may be omitted (e.g., step 122). In an example, process 100 may be implemented for an n-type silicon wafer used as an electron acceptor and an organic electron donor material, or a p-type silicon wafer used as an electron donor and an organic electron acceptor material.

A silicon wafer for use as an electron acceptor or donor in a hybrid solar cell may be selected to increase power conversion efficiency (PCE) of the hybrid solar cell. For example, a silicon wafer with suitable thickness (e.g., about 300 μm) and resistivity (e.g., about 1-5 Ω) may yield a solar cell with a higher PCE than a silicon wafer that is too thick (e.g., 700 μm) or has a high resistivity (e.g., 100 Ω). In step 102, a hard mask layer is formed on the silicon wafer. The hard mask may be, for example, a chromium hard mask formed by sputtering. In step 104, a nanoimprint lithography (NIL) patterning process is used to form a polymeric patterned layer on the silicon wafer, as described herein. In step 106, the residue from step 104 (e.g., resist residue) is removed, and dry etching of the hard mask is performed. (See, for example, Constantine et al., “Plasma etching of Cr photomasks: parametric comparisons of plasma sources and process conditions” (Proceedings Paper), Photomask and X-Ray Mask Technology IV, Naoaki Aizaki, Editors, pp. 11-18, which is incorporated by reference herein.)

In step 108, the silicon wafer is etched. Etching in step 108 may be achieved, for example, with a plasma process including tetrafluoromethane (CF₄) and oxygen. In some cases, the oxygen concentration may be varied or CF₄ may be replaced by SF₆. SF₆ typically gives deeper trenches, while CF₄+O₂ (20%) yields shallower features. In both cases, fluoride polymers may be formed and deposited on the planar surfaces and trenches.

The etched silicon wafer is then cleaned (e.g., with a Piranha solution) in step 110. In some cases, oxygen plasma may be used to remove contaminants from the surface before the cleaning in step 110. The oxygen plasma and cleaning can remove the fluoride polymers that may be formed in step 108. Depending on silicon plasma etching chemistry, it may be difficult to fully clean the surface, for example, when SF₆ is used as the etching gas. In step 112, chromium wet etching is performed to remove remaining chromium from the silicon wafer. The silicon wafer then undergoes cleaning (e.g., Piranha cleaning) in step 114. A length of the cleaning in steps 110 and 114 may be, for example, up to about 30 minutes or longer.

A reflective electrode is deposited on a bottom surface of the etched silicon wafer in step 116. The bottom surface of the silicon wafer can be thought of as the surface opposite the etched surface. The reflective electrode may be, for example, aluminum. The aluminum may be deposited by a process such as sputtering or thermal evaporation, followed by an annealing step to form good contact with the silicon wafer. To remove silicon dioxide that may have formed on the etched surface of the silicon wafer, the etched surface may undergo a buffered oxide etch (BOE) in step 118.

The aluminum deposition, followed by the buffered oxide etch (BOE), increases the hydrophilicity of the silicon surface. The silicon surface with aluminum on the back side, with a water contact angle between about 40° and about 50° after the BOE, is more easily wet by an aqueous electron donor solution than bare silicon following a BOE, which results in a water contact angle of at least about 75°, and thus a more hydrophobic surface.

In some cases, the etched surface of the silicon wafer undergoes additional treatment in step 120 to achieve desired surface properties (e.g, increase the hydrophilicity of the surface). Treatment in step 120 may include, for example, exposure to the air and/or UV ozone treatment. Exposure to air and UV ozone treatment may be used to increase the hydrophilicity (e.g., reduce water contact angle) of the etched surface of the silicon wafer by allowing growth of a silicon dioxide layer on the etched surface of the wafer. For example, after exposure of the etched surface of the silicon wafer to air for about 24 hours, the water contact angle decreases from over 70° to about 50°, and down to less than 30°, forming a dense (native) oxide layer. Exposure of the etched silicon surface to UV ozone treatment for about 5 minutes yields a water contact angle of about 10° or less.

When the desired surface properties are achieved, the organic electron donor or acceptor material may be applied to (e.g., spin-coated on) the patterned surface of the silicon wafer in step 122. After the electron donor material is solidified. The electron donor material may be solidified, for example, by baking at elevated temperature (e.g., for PEDOT:PSS, baking at 100° C. for 10 minutes plus 180° C. for 3 minutes) or vacuum drying and the remaining solvents is completely removed, the transparent electrode is deposited in step 124. In some cases, a metal grid may be used in place of a transparent electrode.

In a hybrid solar cell, electron donor and acceptor materials may be selected to maximize absorption of solar radiation. Absorption in the visible region of the solar radiation spectrum by silicon (e.g., as an electron acceptor) may be complemented with organic material (e.g., as an electron donor) that absorbs in another region of the spectrum. PEDOT:PSS is substantially transparent in the visible region, but absorbs infrared radiation. Thus, using silicon as an electron acceptor and PEDOT:PSS as an electron donor provides absorbance across the solar radiation spectrum, in contrast to other combinations of n-type and p-type materials (e.g., silicon and P3HT, CuPC, ZnPC, or NiPC) that absorb in a limited region of the solar radiation spectrum. In addition, PEDOT:PSS is non-toxic, stable in air up to about 250° C., and can be dispersed in aqueous solutions. With a layer thickness between about 100 nm and about 300 nm, PEDOT:PSS provides high electrical conductivity and transmission of visible light. In an example, process 100 may be used to form a hybrid organic-inorganic solar cell with etched n-type silicon as the electron acceptor and PEDOT:PSS as the electron donor. In some cases, PEDOT:PSS can be used as a p-type material as well as a collecting anode electrode with no buffer layer, thus reducing the number of processing steps required.

Surface treatment of the etched surface of a silicon wafer may be selected such that the organic electron donor or acceptor material wets the silicon wafer, filling the recesses between protrusions in the etched silicon wafer and forming a substantially continuous layer of the organic electron donor or acceptor material on the silicon wafer, but not over treated to form a dense oxide layer, leading to the substantial increase of the interface resistivity. For example, the length of time an etched silicon wafer is exposed to the environment or UV ozone treatment may be selected to achieve a desired water contact angle (e.g., about 40° to about 50°), such that the organic electron donor or electron acceptor wets the etched surface and substantially fills all the recesses, while not increasing the resistivity significantly (e.g., less than about a 20% increase, less than about a 10% increase, or less than about a 5% increase). In some cases a very thin layer (e.g., continuous monolayer or a discontinuous monolayer) of oxide helps to increase the wettability of the silicon, but not substantially increase the surface resistivity.

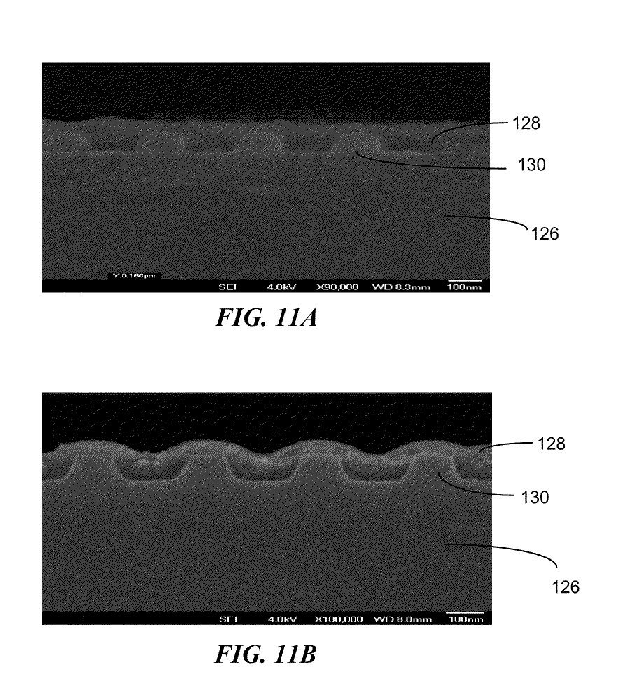

FIGS. 11A and 11B are scanning electron micrographs of etched n-type silicon wafers 126 (150 nm pillars or protrusions) with polymer 128 (PEDOT:PSS) between protrusions 130 in the silicon wafer. In FIG. 11A, aqueous PEDOT:PSS was spin-coated on etched silicon with aluminum sputtered on the back side after the buffered oxide etch. The aqueous PEDOT:PSS was able to fill in the trenches with a depth of 60 nm. In FIG. 11B, aqueous PEDOT:PSS was spin-coated on etched n-type silicon after the surface received a 5 minute UV ozone treatment. The aqueous PEDOT:PSS was able to fill in the trenches to a depth of 100 nm. Thus, the UV ozone treatment was shown to improve wettability of the etched n-type silicon with respect to the aqueous PEDOT:PSS.

As a comparative example, a planar hybrid organic-inorganic solar cell was fabricated similarly to process 100 (i.e., without formation of a patterned layer). The planar solar cell was a silicon-containing, dye-free, hybrid solar cell with no patterned layer. A PCE of 7.7% was achieved with active layers of PEDOT:PSS, assuming a fill factor of 0.63. Solar cells were also fabricated according to process 100, with the silicon patterned layer having a pitch of 120 nm, 1:1 L/S, and 60 nm in depth. For the patterned solar cells, PCE ranged from 9.2% to 10.8%.

Variations in the treatment of the etched silicon surface during process 100 were shown to affect the PCE of the resulting hybrid solar cell. For example, a 10 minute UV ozone treatment reduced the PCE of the solar cell to less than 0.77%, or less than 10% of the PCE for a solar cell formed by process 100 without the UV ozone treatment. A 5 minute UV ozone treatment reduced the PCE of the solar cell to about 7%, or about 90% of the PCE for a solar cell formed by process 100 without the UV ozone treatment. A 2 minute UV ozone treatment did not cause any noticeable reduction in PCE compared to a solar cell formed by process 100 without the UV ozone treatment.

These results suggest that the thickness of silicon dioxide formed on the surface of the etched silicon wafer during the UV ozone treatment can be controlled to limit the effect on PCE while making the surface more hydrophilic and lowering the water contact angle. Thus, a limited exposure to UV ozone treatment can make the etched silicon surface more hydrophilic, and improve filling, without much increase in interfacial resistivity—and therefore without much loss in PCE compared to a hybrid solar cell fabricated according to FIG. 10 without UV ozone treatment. It is believed that initial growth of the silicon dioxide surface (e.g., as seen following a 2 minute UV ozone treatment) may not form a continuous layer on the silicon surface, allowing good conductivity at the areas without silicon dioxide and improving hydrophilicity in the oxidized regions.

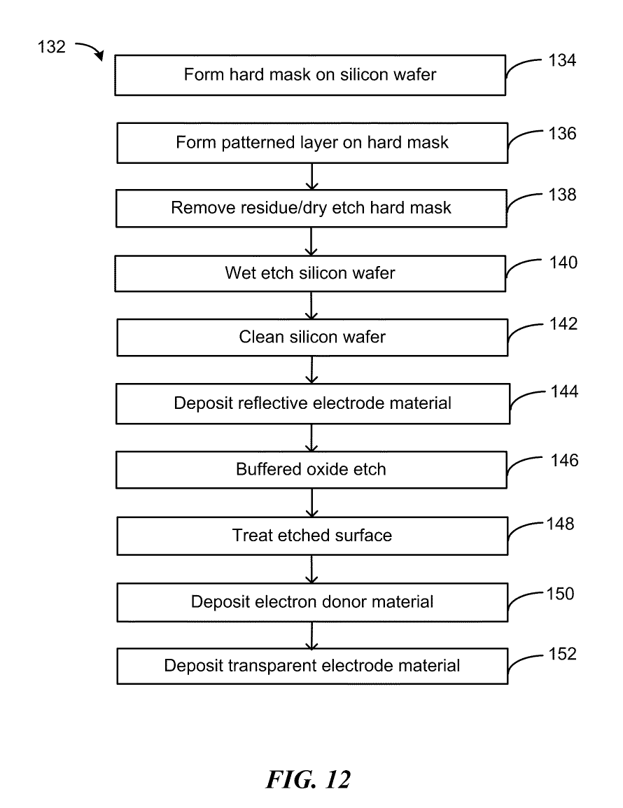

In some cases, a wet etching of silicon wafer with KOH is carried out to pattern a surface of the wafer. In this process, crystal structure of the silicon wafer (e.g., 110, 111, 100, etc) may be selected to achieve desired patterns. The flow chart in FIG. 12 shows steps in process 132 to form a hybrid organic-inorganic solar cell using wet etching of an electron acceptor with potassium hydroxide (KOH). In some cases, one or more steps in process 132 may be performed in an order other than that shown in FIG. 12. In certain cases, one or more steps in process 132 may be omitted (e.g., step 142). As an example, the process is described with a silicon wafer as the electron acceptor.

In step 134, a hard mask (e.g., a chromium hard mask) is formed on a silicon wafer. In step 136, a nanoimprint lithography (NIL) process is used to form a patterned layer on the silicon wafer. In step 138, the resist residue layer is removed by dry etching. Step 140 includes a wet etching of the silicon wafer (e.g., with KOH). In step 142, the silicon wafer undergoes cleaning (e.g., Piranha cleaning). In step 144, back (reflective) electrode material is deposited on a surface of the silicon wafer opposite the patterned surface. Step 146 includes buffered oxide etching of the silicon wafer, and step 148 includes treating silicon wafer (e.g., with a UV ozone treatment). In step 150, an organic active layer (e.g., p-type material) is dispose on the silicon wafer (e.g., with spin coating). Front (transparent) electrode material is deposited on the organic active layer in step 152.

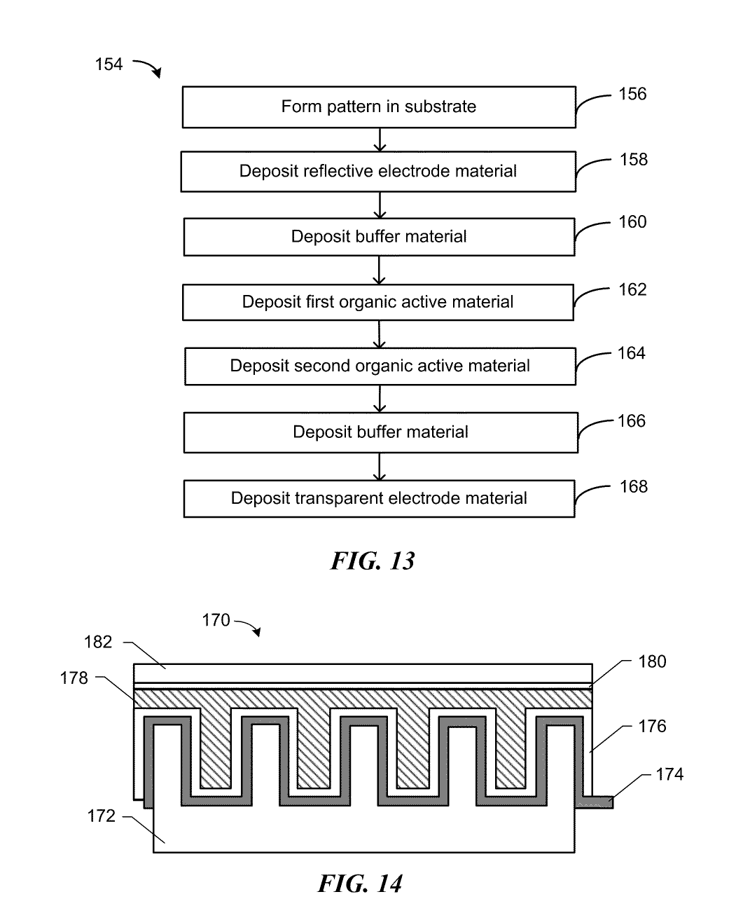

Referring to the flowchart in FIG. 13, a process 154 for fabricating an organic solar cell using nanoimprint lithography is described, in which organic active layers are deposited on a patterned substrate. In some cases, one or more steps in process 154, such as step 160, may be omitted. The resulting solar cells differ from those described in FIGS. 9A and 9B, in that the substrate, rather than an active layer, is patterned by nanoimprint lithography.

In step 156, nanoimprint lithography is used to define a pattern on a substrate. The substrate may include, for example, polymeric material, such as polyethylene terephthalate (PET), or other material, such as silicon. In step 158, a reflective electrode material is deposited on the patterned substrate, forming a conformal layer on the substrate. The reflective electrode material may include any low work function metal or a mixture thereof, including, for example, aluminum, calcium, magnesium, and the like. In step 160, a conformal layer of a buffer material may be deposited on the reflective electrode formed in step 158. The buffer material may include, for example, LiF, CaF₂, or the like. In step 162, a first organic active layer is deposited as a conformal layer on the buffer layer or the reflective electrode. The first organic active layer may be, for example, an n-type material that serves as an electron acceptor, such as C60, PCBM, TiO₂, ZnO, and the like. In step 164, a second organic layer is deposited in the recesses defined by the first organic layer. The second organic active layer may be a conformal layer or a planar layer. The second organic active layer may be, for example, a p-type material that serves as an electron donor material, such as P3HT, PPV, CuPc, ZnPc, and the like. In step 166, a buffer layer is deposited on the second organic layer. The buffer layer may include, for example, PEDOT:PSS. In step 168, a transparent electrode material is deposited on the buffer layer. The transparent electrode may include any high work function metal or a mixture thereof. In some cases, the transparent electrode includes ITO, FTO, etc. In certain cases, a metal grid formed of copper, gold, silver, or the like may be used instead of a transparent electrode. In some embodiments, an organic solar cell may be formed in substantially the reverse order from that shown in process 154.

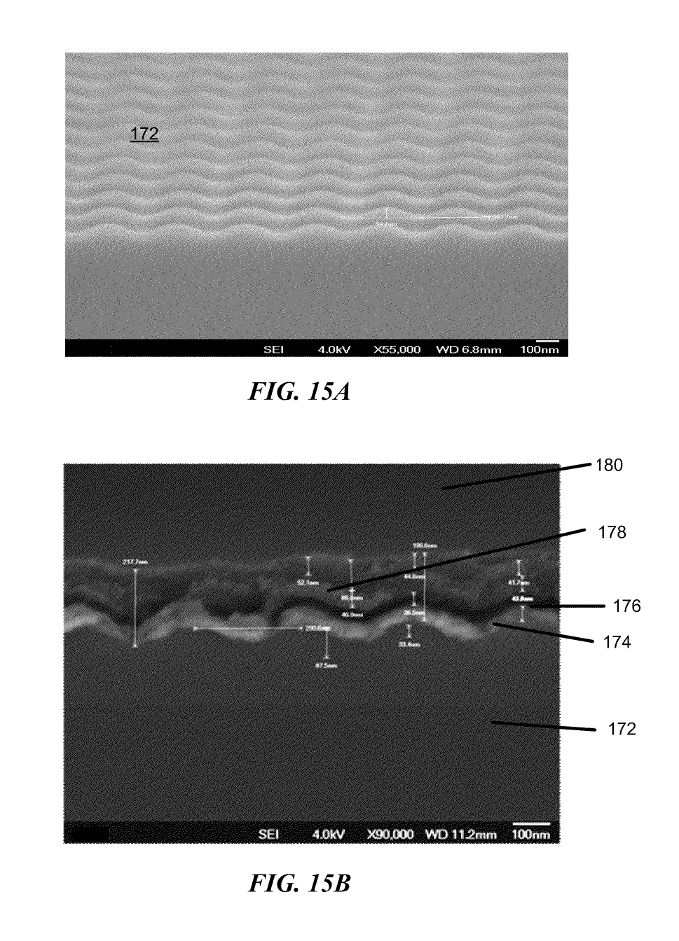

FIG. 14 illustrates a cross section of an organic solar cell 170 formed by process 154. Organic solar cell 170 includes patterned substrate 172, reflective electrode 174, electron acceptor layer 176, electron donor layer 178, buffer layer 180, and transparent electrode 182. FIG. 15A shows a scanning electron micrograph of a patterned silicon substrate 172 formed by nanoimprint lithography for use in an organic solar cell. FIG. 15B shows a scanning electron micrograph of a patterned organic solar cell stack, with patterned substrate 172 formed from silicon, reflective electrode 174 formed from aluminum, n-type material 176 formed from C60, p-type material 178 formed from CuPc, and buffer layer 180 formed from PEDOT:PSS. The aluminum, C60, and CuPc were deposited sequentially in a chamber under a vacuum (e.g., about 1×10⁻⁶ Torr for C60 and CuPc) by thermal evaporation.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description. Changes may be made in the elements described herein without departing from the spirit and scope as described in the following claims.

What is claimed is:

1. A method of fabricating a solar cell stack, the method comprising:
forming a nanopatterned polymeric layer on a first surface of a silicon wafer;
etching the first surface of the silicon wafer to transfer a pattern of the nanopatterned polymeric layer to the first surface of the silicon wafer, thereby forming a nanopatterned first surface of the silicon wafer having recessions and protrusions;
forming a layer of a reflective electrode material on a second surface of the silicon wafer, wherein the second surface of the silicon wafer is opposite the nanopatterned first surface of the silicon wafer;
buffered oxide etching the nanopatterned first surface of the silicon wafer after forming the layer of reflective electrode material on the second surface of the silicon wafer;
treating the nanopatterned first surface of the silicon wafer after buffered oxide etching to decrease a contact angle of water on the nanopatterned first surface of the silicon wafer;
depositing electron donor material on the nanopatterned first surface of the silicon wafer to form an electron donor layer on the nanopatterned first surface of the silicon wafer; and
depositing a transparent electrode material on the electron donor layer to form a transparent electrode layer on the electron donor layer.

2. The method of claim 1, wherein etching the first surface of the silicon wafer comprises a dry etching process.

3. The method of claim 1, wherein etching the first surface of the silicon wafer comprises a wet etching process.

4. The method of claim 3, wherein the wet etching process comprises wet etching with potassium hydroxide.

5. The method of claim 1, wherein the reflective electrode material comprises aluminum.

6. The method of claim 5, wherein the contact angle of water on the nanopatterned first surface of the silicon wafer after buffered oxide etching is between about 40° and about 50°.

7. The method of claim 1, wherein treating the nanopatterned first surface of the silicon wafer after buffered oxide etching comprises UV ozone treatment of the silicon wafer.

8. The method of claim 7, wherein a resistivity of the silicon wafer following the UV ozone treatment is about 120% or less of the resistivity of the silicon wafer before the UV ozone treatment.

9. The method of claim 1, further comprising cleaning the nanopatterned first surface of the silicon wafer before forming the layer of the reflective electrode material on the second surface of the silicon wafer.

10. The method of claim 1, wherein the electron donor material comprises poly(3,4-ethylenedioxythiophene) poly(styrenesulfonate) (PEDOT:PSS).

11. The method of claim 1, wherein the transparent electrode material comprises poly(3,4-ethylenedioxythiophene) poly(styrenesulfonate) (PEDOT:PSS).

12. The method of claim 1, wherein depositing the electron donor material on the nanopatterned first surface of the silicon wafer comprises electrodepositing the electron donor material in recessions of the nanopatterned first surface of the silicon wafer.

13. A solar cell stack formed by the method of claim 1.

14. A solar cell comprising a solar cell stack formed by the method of claim 1.

15. A method of fabricating a solar cell stack, the method comprising:
patterning a surface of a substrate to form a nanopatterned surface;
depositing a conformal layer of a reflective electrode material on the nanopatterned surface of the substrate;
depositing a conformal layer of a first electrically conductive organic material on the reflective electrode material;
depositing a layer of a second electrically conductive organic material on the first electrically conductive organic material;
depositing a buffer material on the second electrically conductive organic material; and
depositing a transparent electrode material on the buffer material.

16. The method of claim 15, wherein depositing the layer of the second electrically conductive organic material on the first electrically conductive organic material comprises filling recesses and covering protrusions in the conformal layer of the first electrically conductive organic material with the second electrically conductive organic material.

17. The method of claim 15, wherein the buffer material comprises poly(3,4-ethylenedioxythiophene) poly(styrenesulfonate) (PEDOT:PSS).

18. The method of claim 15, further comprising depositing a second buffer material between the reflective electrode material and the first electrically conductive organic material.

19. A solar cell stack formed by the method of claim 15.

20. A solar cell comprising a solar cell stack formed by the method of claim 15.
